(19) United States
(12) Patent Application Publication
(10) Pub. No.: US 2026/0123240 A1
(43) Pub. Date: Apr. 30, 2026

(54) DISPLAY DEVICE

(71) Applicant: LG Display Co., Ltd., Seoul (KR)

(72) Inventors: Seung Han PAEK, Paju-si (KR); Nam Woo KIM, Paju-si (KR); Yong In PARK, Paju-si (KR); Kyung Jae YOON, Paju-si (KR); Yu Cheol YANG, Paju-si (KR)

(73) Assignee: LG Display Co., Ltd., Seoul (KR)

(21) Appl. No.: 19/003,922

(22) Filed: Dec. 27, 2024

(30) Foreign Application Priority Data
Dec. 29, 2023 (KR) 10-2023-0197375

(51) Int. Cl. H10K 59/80; H10K 59/122; H10K 102/00

(52) U.S. Cl. CPC H10K 59/873; H10K 59/122; H10K 2102/311

(57) ABSTRACT

A display device includes a substrate; a display area on the substrate, the display area including a plurality of pixels; a non-display area outside the display area on the substrate and including a display driver; and a bending area between the display area and the non-display area. The substrate may include a first glass substrate in the display area, a second glass substrate in the non-display area, and a third glass substrate in the bending area and having a pattern.

### CROSS-REFERENCE TO RELATED APPLICATION

This application claims priority to and the benefit of Korean Patent Application No. 10-2023-0197375, filed on Dec. 29, 2023, the disclosure of which is incorporated herein by reference in its entirety.

### BACKGROUND

### 1. Field

The present disclosure relates to a display device.

### 2. Discussion of Related Art

Display devices are applied to various electronic devices, such as TVs, mobile phones, laptop computers, and tablet computers. Therefore, research is continuing to develop display devices that are smaller, thinner, and lighter and have lower power consumption.

Among the display devices, liquid crystal display devices, self-emitting display devices, and electrophoretic display devices can be configured to be thinner.

Recently, the miniaturization of mobile communication terminals, such as smart phones and tablet PCs, among the display devices, is being pursued. In addition, research and development are being conducted to realize a maximum display screen area in a display device of the same size by implementing a narrow bezel and reducing a bezel area where images are not displayed.

### SUMMARY

The present disclosure is directed to a display device that substantially obviates one or more of the problems due to limitations and disadvantages of the related art.

The present disclosure is directed to providing a display device in which a display area substrate, a bending area substrate, and a non-display area substrate may be manufactured without performing any additional processing, or with a reduced amount of additional processing, on a mother glass substrate.

The present disclosure is also directed to providing a display device in which the reliability of a bending area can be improved, the size of the bending area can be reduced, and thus the width of a bezel area can be minimized or reduced.

The objects of the present disclosure are not limited to the above-described objects, and other objects can be clearly understood by those skilled in the art from the following description.

To achieve these objects and other advantages of the present disclosure, as embodied and broadly described herein, a display device may include a display area on a substrate, the display area including a plurality of pixels; a non-display area outside the display area on the substrate and including a display driver; and a bending area between the display area and the non-display area. The substrate may include a first glass substrate in the display area, a second glass substrate in the non-display area, and a third glass substrate in the bending area and having a pattern.

In another aspect of the present disclosure, a display device may include a first substrate including a plurality of pixels configured to display an image; a second substrate spaced apart from the first substrate and including a display pad electrically connected to at least one of the pixels; and a third substrate between the first substrate and the second substrate, the third substrate being formed in a pattern and being bent. The third substrate may have a smaller thickness than each of the first substrate and the second substrate.

Additional features and aspects of the disclosure will be set forth in the description that follows and in part will become apparent from the description or may be learned by practice of the inventive concepts provided herein. Other features and aspects of the inventive concepts may be realized and attained by the structure particularly pointed out in, or derivable from, the written description, claims hereof, and the appended drawings.

It is to be understood that both the foregoing general description and the following detailed description of the present disclosure are by way of example and are intended to provide further explanation of the disclosures as claimed.

### BRIEF DESCRIPTION OF THE DRAWINGS

The accompanying drawings, which are included to provide a further understanding of the disclosure and are incorporated in and constitute a part of this application, illustrate example embodiments of the disclosure and together with the description serve to explain the principles of the disclosure. In the drawings

FIG. 1 is a block view illustrating a display panel and a driving unit of a display device according to an example embodiment of the present disclosure;

FIG. 2 is a schematic perspective view of a glass substrate for describing a bending direction of a glass substrate according to an example embodiment of the present disclosure;

FIG. 3A is a plan view of a glass substrate according to an example embodiment of the present disclosure;

FIG. 3B is a plan view of a glass substrate according to another example embodiment of the present disclosure;

FIGS. 4A and 4B are views illustrating an example pattern or patterns according to an example embodiment of the present disclosure;

FIGS. 5A to 5F are example cross-sectional views along line I-I′ in FIG. 1, illustrating a method of manufacturing a glass substrate of a display device according to an example embodiment of the present disclosure;

FIG. 6A is a cross-sectional view of a display device in a bent or folded state according to an example embodiment of the present disclosure;

FIG. 6B is an enlarged cross-sectional view of area “B” in FIG. 6A;

FIG. 6C is an enlarged view of a bending area according to another example embodiment of the present disclosure;

FIGS. 7A to 7F are example cross-sectional views along line II-II′ in FIG. 1, illustrating various examples of one or more bending lines in an etch stop layer and a third glass substrate disposed in a bending area of a display device according to example embodiments of the present disclosure; and

FIG. 8 is an enlarged view of a bending area according to still another example embodiment of the present disclosure.

### DETAILED DESCRIPTION

Reference will now be made in detail to various embodiments of the present disclosure, examples of which may be illustrated in the accompanying drawings.

Advantages and features of the present disclosure, and implementation methods thereof will be clarified through following example embodiments described with reference to the accompanying drawings. The present disclosure may, however, be embodied in different forms and should not be construed as limited to the example embodiments set forth herein. Rather, these example embodiments are provided so that this disclosure may be sufficiently thorough and complete to assist those skilled in the art to fully understand the scope of the present disclosure.

In the following description, where a detailed description of a relevant known function or configuration may unnecessarily obscure aspects of the present disclosure, a detailed description of such known function or configuration may be omitted.

The shapes, sizes, ratios, angles, numbers, and the like, which are illustrated in the drawings to describe various example embodiments of the present disclosure, are merely given by way of example. Therefore, the present disclosure is not limited to the illustrations in the drawings.

Like reference numerals designate like elements throughout, unless otherwise specified. Names of the respective elements used in the following explanations are for convenience of description and may thus be different from those used in actual products.

Terms like “including,” “having,” “containing,” “constituting,” “made up of,” and “formed of” used herein are generally intended to allow inclusion or addition of one or more other components unless the terms are used with a more limiting term, such as “only” or the like. As used herein, singular forms are intended to include plural forms unless the context clearly indicates otherwise.

Although the terms “first,” “second,” A, B, (a), (b), and the like may be used herein to describe various elements, these elements should not be interpreted to be limited by these terms as they are not used to define a particular order, sequence, precedence, or number of such elements. These terms are used only to refer to one element separately from another. For example, a first element could be termed a second element, and a second element could similarly be termed a first element, without departing from the scope of the present disclosure.

Where an expression that an element or layer “is connected to,” “is coupled to,” “is adhered to,” “contacts,” or “overlaps” another element or layer is used, the element or layer not only can be directly connected, coupled, or adhered to or directly contact or overlap another element or layer, but also can be indirectly connected, coupled, or adhered or indirectly contact or overlap another element or layer with one or more intervening elements or layers “disposed” or “interposed” between the elements or layers, unless otherwise specified.

Where positional relationships are described, for example, where the positional relationship between two parts is described using “on,” “over,” “under,” “above,” “below,” “beside,” “next,” or the like, one or more other parts may be located between the two parts unless a more limiting term, such as “immediate (ly),” “direct (ly),” or “close (ly)” is used. For example, where an element or layer is described as disposed “on” another element or layer, a third element or layer may be interposed therebetween.

In addition, where any dimensions, relative sizes, and the like are discussed, numerical values for an elements or features, or corresponding information (e.g., level, range, etc.) should be considered to include a tolerance or error range that may be caused by various factors (e.g., process factors, internal or external impact, noise, etc.) even where no explicit description of such a tolerance or error range is provided. Further, the term “may” fully encompasses all the meanings of the term “can”.

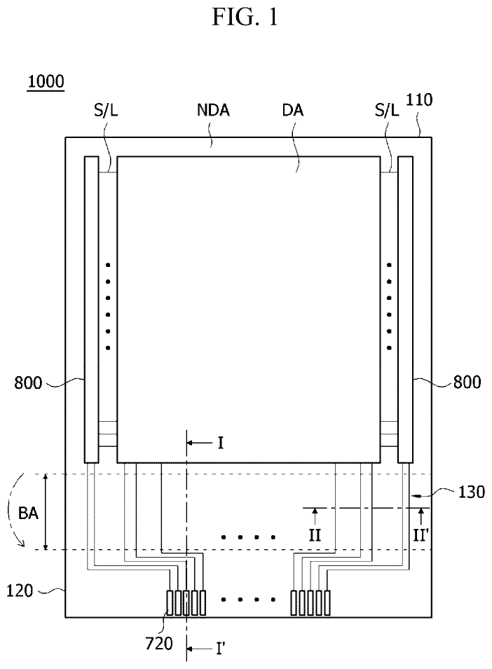

FIG. 1 is a block view illustrating a display panel and a driving unit of a display device according to an example embodiment of the present disclosure.

As shown in FIG. 1, the display device 1000 according to an example embodiment of the present disclosure may include a display area DA disposed on a first glass substrate (or first substrate) 110 and a non-display area NDA surrounding the display area DA. The display area DA is an area configured to display an image and may be supported by the first glass substrate 110. The display area DA may include a plurality of pixels. The plurality of pixels may be arranged in a matrix form, and each of the plurality of pixels may include sub-pixels. The display area DA may have a substantially rectangular shape. However, the embodiments of the present disclosure are not limited thereto, and the display area DA may have any one of various other shapes, such as various polygonal shapes. For example, depending on a shape of the display device, the display area may have a triangular, pentagonal, or hexagonal shape. In this application, for convenience of description, an example display area DA having a rectangular shape will be described below according to an example display device 1000 having a rectangular shape.

The non-display area NDA may be an area surrounding the display area DA and may include elements and circuit lines for driving elements and/or circuits, such as pixel elements and/or circuits, in the display area DA.

A bending area BA may be disposed at one side or one end of the non-display area NDA on the first glass substrate 110. The bending area BA may be disposed between the display area DA and the non-display area NDA. The bending area BA may be defined as an area formed so that a portion of the non-display area NDA of the display device 1000 is bent. Therefore, the display device according to example embodiments of the present disclosure may be folded or bent to have a constant radius of curvature depending on the degree of folding of the bending area BA.

An area disposed at one side or one end of the bending area BA of the non-display area NDA may be defined as a display pad portion. The display pad portion may be formed on a second glass substrate (or second substrate) 120 and may be attached to a rear surface of the first glass substrate 110 with an adhesive or the like. The first glass substrate 110 may be disposed in the display area DA. The second glass substrate 120 may be disposed in the non-display area NDA. In the display pad portion, lines, pads, and the like provided for driving a display panel of the display device 1000, such as a display pad 720 or the like, may be disposed.

In the non-display area NDA formed on the first glass substrate 110 at one or more sides of the display area DA at which the bending area is not disposed, one or more driving circuits for driving elements in the display area DA, such as a gate driving circuit 800, and circuit lines S/L connected between the driving circuit(s) and the elements in the display area DA, may be disposed.

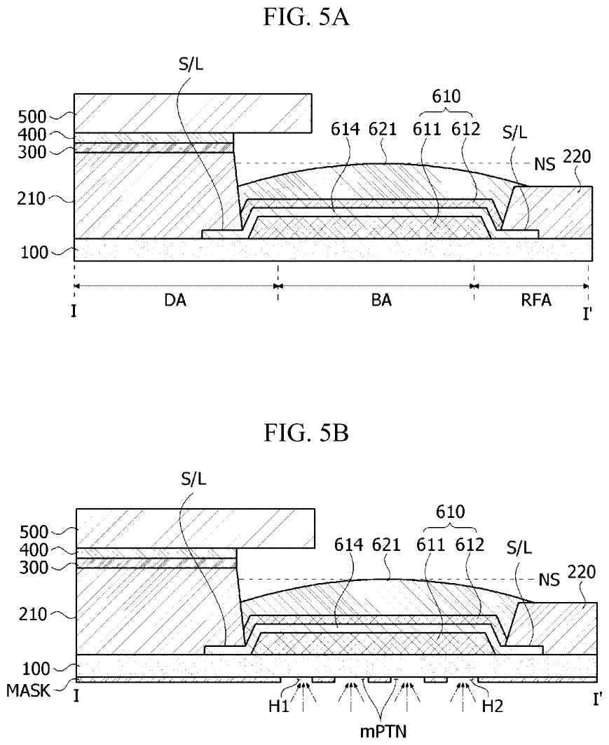

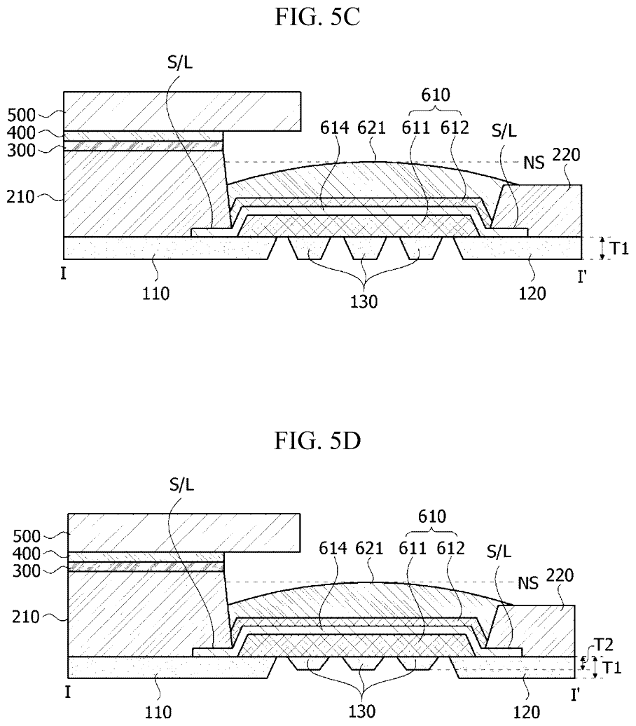

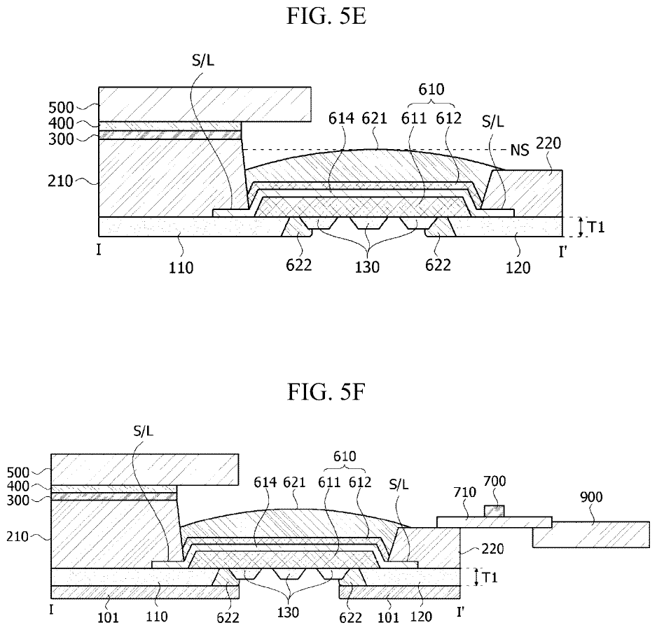

A pixel array layer, a protective layer, and a touch sensor layer may be sequentially formed on an upper surface of the first glass substrate 110. Then, the glass substrate 100 (see, e.g., FIGS. 5A to 5F) may undergo a thinning process. In this case, the first glass substrate 110 and the second glass substrate 120 may be formed from respective portions of the glass substrate 100 and may each have a first thickness.

A third glass substrate (or third substrate) 130 may be disposed in the bending area BA and may be bent. Thus, in consideration of stress during bending, one or more patterns PTN may be configured in the third glass substrate 130 disposed in the bending area BA, and the third glass substrate 130 may have a second thickness that is smaller than the first thickness of each of the first glass substrate 110 and the second glass substrate 120. The thickness difference between the glass substrates will be described in more detail below.

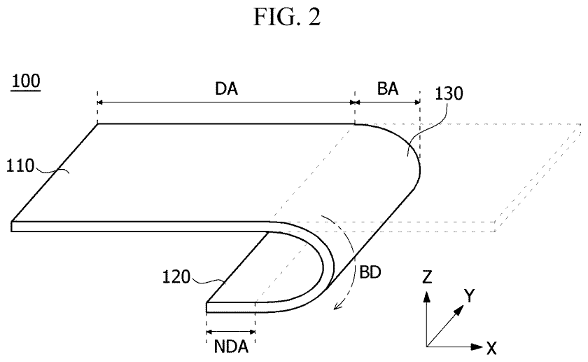

FIG. 2 is a schematic perspective view of a glass substrate 100 (including the first, second and third glass substrates 110, 120, 130) for describing a bending direction of the glass substrate 100 according to an example embodiment of the present disclosure.

In FIG. 2, for convenience of description, the non-display area NDA disposed at an outer periphery of the display area DA of the first glass substrate 110 is omitted. However, portions of the non-display area NDA in which the gate driving circuit 800 or the like is disposed may be formed on the first glass substrate 110 at the outer periphery of the display area DA where the bending area BA is not disposed.

As illustrated in FIG. 2, a bending area BA of the glass substrate 100 may be bent in a bending direction BD. For example, bending the bending area BA of the glass substrate 100 may mean that one side of the glass substrate 100 located in a positive direction of an X-axis in the bending area BA of the glass substrate 100 located on an XY plane is gradually bent from the positive direction of the X-axis via a negative direction of a Z-axis toward a negative direction of the X-axis. In addition, as shown in FIG. 2, the bending direction BD of the bending area BA means a direction perpendicular to a boundary between the display area DA and the bending area BA (e.g., a dotted line between the display area DA and the bending area BA in FIG. 2). That is, the bending direction BD of the bending area BA means a positive direction of the x-axis, which is the direction toward the bending area BA from the boundary between the display area DA and the bending area BA among directions perpendicular to a YZ plane in which the boundary between the display area DA and the bending area BA is located.

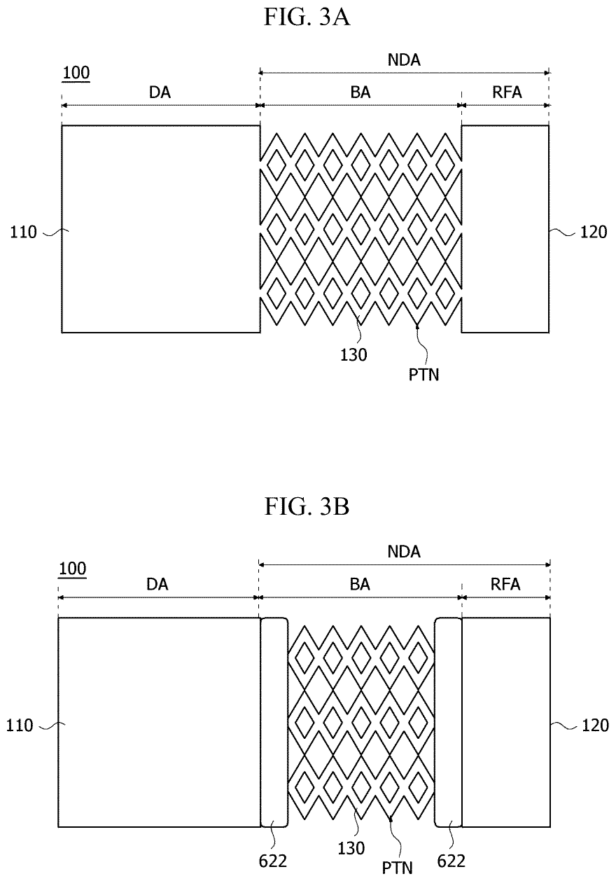

FIGS. 3A and 3B are plan views of a glass substrate according to example embodiments of the present disclosure.

As shown in FIG. 3A, the glass substrate 100 may include (1) the first glass substrate 110 on which the display area DA is disposed, (2) the second glass substrate 120 that may overlap the display pad portion (where the driving circuit and the display pad 720 may be disposed) in the non-display area NDA and may be attached to the rear surface of the first glass substrate 110 with an adhesive or the like, and (3) the third glass substrate 130 disposed in the bending area BA between the first glass substrate 110 and the second glass substrate 120.

An area of the second glass substrate 120 not overlapping the bending area BA of the non-display area NDA and attached to the rear surface of the first glass substrate 110 with the adhesive or the like may be defined as a rear flat area RFA. The rear flat area RFA may be smaller than the display area DA.

One or more patterns PTN may be formed on the third glass substrate 130. At least some of the patterns PTN of the third glass substrate 130 may extend in a diagonal direction with respect to the boundary between the display area DA and the bending area BA and with respect to the bending direction BD of the bending area BA. Therefore, as the bending area BA of the glass substrate 100 is bent, the stress received by the third glass substrate on which a plurality of patterns PTN are disposed may be reduced, thereby minimizing or reducing the occurrence of cracks in the third glass substrate 130. Accordingly, the occurrence of cracks in bending lines 614 formed in an etch stop layer 610 (see, e.g., FIGS. 5A to 5F) above the third glass substrate 130 may be prevented or reduced.

FIG. 3B is a plan view of a glass substrate according to another embodiment of the present disclosure.

As illustrated in FIG. 3B, to reduce the stress received by the glass substrate and stress during bending, a coating layer, for example, a micro coating layer 622 may be disposed between the first glass substrate 110 and the third glass substrate 130 and between the second glass substrate 120 and the third glass substrate 130.

Since cracks may occur in the micro coating layer 622 due to a tensile force during bending, the micro coating layer 622 may serve to protect the lines and substrate by forming a thin layer made of such materials as a resin at the bending location. The micro coating layer 622 may be made of an acrylic material, such as an acrylate polymer, but is not limited thereto. In FIG. 3B, the micro coating layer 622 is illustrated as being disposed only between the first glass substrate 110 and the third glass substrate 130 and between the second glass substrate 120 and the third glass substrate 130, but the present disclosure is not limited thereto. For example, the micro coating layer 622 may fill all of the empty spaces of the fine patterns PTNs of the third glass substrate 130 or may be disposed to cover the entire third glass substrate.

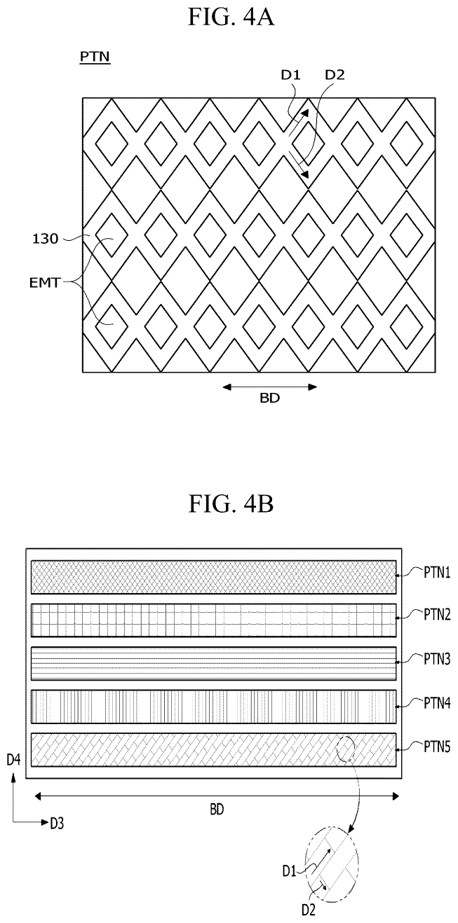

FIGS. 4A and 4B are views illustrating a pattern or patterns according to an example embodiment of the present disclosure.

As shown in FIG. 4A, one or more patterns PTN may extend in directions D1 and D2 that are different from the bending direction BD of the bending area BA. By forming the patterns PTN of the third glass substrate 130 to extend in a direction different from the bending direction BD, the stress received by the third glass substrate can be reduced. Additionally, as the patterns PTN extend in a direction different from the bending direction BD, empty spaces EMT may be formed between the patterns PTN. Due to the patterns PTN configured in this manner, the stress that the third glass substrate 130 receives during bending may be reduced, and as the stress decreases, the occurrence of cracks in the third glass substrate 130 during bending can also be reduced.

As illustrated in FIG. 4B, the patterns PTN in example embodiments of the present disclosure may include various types of second to fifth patterns PTN2, PTN3, PTN4, and PTN5 in addition to a first pattern PTN1 illustrated FIG. 4A. Patterns according to example embodiments of the present disclosure may include, for example, (1) a grid-like or mesh-like pattern PTN2 formed by being extended in a direction D3, which is the same as the bending direction BD, and in a direction D4 perpendicular to the bending direction BD of the bending area BA, (2) stripe-type patterns PTN3 and PTN4 that extend in either the straight direction D3, which is the same as the bending direction BD, or the perpendicular direction D4, and (3) a zig-zag-like pattern PTN5 that extends in directions D1 and D2, which are different from the bending direction BD in the same manner as the first pattern PTN1 or extends in a direction diagonal to a bending direction BD, but with the length of the pattern extending in the first direction D1 being different from the length of the pattern extending in the second direction D2. The present disclosure is not limited to these example patterns PTN, and a variety of any other patterns that can distribute stress during bending can be used.

FIGS. 5A to 5F are views illustrating a method of manufacturing a glass substrate of a display device according to an example embodiment of the present disclosure.

As shown in FIG. 5A, the display device 1000 may include the glass substrate 100, a pixel array layer 210, a display pad portion 220, an etch stop layer 610, a first micro coating layer 621, a polarizing layer 300, a first adhesive layer 400, and a cover glass 500.

The pixel array layer 210 may be disposed in the display area DA on the glass substrate 100. The pixel array layer 210 may be provided in a pixel area defined by pixel driving lines (not illustrated) provided on the display area DA and may include a plurality of pixels configured to display an image according to signals supplied to the pixel driving lines. Here, the pixel driving lines may include, for example, data lines, gate lines, and pixel driving power supply lines. Each of the plurality of pixels may include, for example, a pixel circuit layer, an anode electrode layer, a self-emitting element layer, and a cathode electrode layer.

The pixel array layer 210 may be provided in a transistor area of each pixel area and may be driven according to signals supplied from adjacent pixel driving lines to control the light emission of the self-emitting element layer. The pixel array layer 210, for example, may include at least two thin film transistors (including a driving thin film transistor) provided in the transistor area of each pixel area defined on the first glass substrate 110 and at least one capacitor. Here, the pixel circuit layer may include at least one TFT type among an a-Si TFT, a poly-Si TFT, an oxide TFT, and an organic TFT.

The anode electrode layer may be electrically connected to the driving thin film transistor. The self-emitting element layer may be formed on the anode electrode layer provided in an opening area of each pixel. Here, the opening area of each pixel area may be defined by a bank pattern formed on an overcoat layer to cover an edge of the anode electrode layer.

The self-emitting element layer may include, for example, an organic light-emitting element, a quantum dot light-emitting element, or an inorganic light-emitting element. For example, the self-emitting element layer may be formed in a structure in which a hole injection layer, a hole transport layer, an organic light-emitting layer, an electron transport layer, and an electron injection layer are sequentially stacked. Here, one or more of the hole injection layer, the hole transport layer, the electron transport layer, and the electron injection layer may be omitted. The organic light emitting layer may be formed to emit light of the same color, for example, white light, for each pixel, or may be formed to emit light of a different color, for example, red, green, blue, or white, for each pixel.

The polarizing layer 300, the first adhesive layer 400, and the cover glass 500 sequentially disposed on the pixel array layer 210 may be included in the display device 1000.

The polarizing layer 300 may include a linear polarizer and a phase retardation film. The polarizing layer 300 may improve outdoor visibility by preventing light incident from the outside of the display device 1000 from being reflected by and emitted from a metal layer inside the display device 1000.

External non-polarized light may pass through a linear polarizer with a light transmission axis of 90 degrees. Only the transmitted linearly polarized light with the same light transmission axis as the linear polarizer passes through the phase retardation film, becomes circularly polarized at 135 degrees, and can be incident on (or reflected by) the TFT or an electrode inside the display device. The reflected circularly polarized light may pass through the phase retardation film again and may become linearly polarized light retarded by a total of 180 degrees. All linearly polarized light retarded by 180 degrees may be absorbed by the linear polarizer with a light transmission axis of 90 degrees, thereby preventing light incident from the outside of the display device 1000 from being reflected by and emitted from an internal metal layer of the display device 1000. A configuration of the polarizing layer is not limited to the above example, and any other structure of the polarizing layer that improves outdoor visibility can be used.

The first adhesive layer 400 may include a pressure-sensitive adhesive, a foam-type adhesive, a liquid adhesive, a light-cured adhesive, or one or more of other suitable adhesive materials. In some embodiments, the first adhesive layer 400 may be formed of or include a compressible material and may function as a buffer material for a portion adhered by the first adhesive layer 400. As an example, the constituent material of the first adhesive layer 400 may be compressible. The first adhesive layer 400 may be formed in a multilayer structure, and the multilayer structure may include a buffer layer disposed between upper and lower layers of the adhesive material layer.

The cover glass 500 may be disposed to cover an entire upper surface (or a front viewing surface) of the display device 1000 and the bending area BA and may serve to protect the display device 1000 from external impacts. The cover glass 500 may be, for example, made of a transparent plastic material, a glass material, or a tempered glass material.

The etch stop layer 610 may be disposed above the location where the glass substrate 100 is etched.

The etch stop layer 610 may be disposed between the display pad portion 220 and the pixel array layer 210. To prevent an etching solution from penetrating into or through the substrate 100 when the substrate 100 is etched, the etch stop layer 610 may be disposed in a portion of the display area DA near where the glass substrate 100 is separated into the first glass substrate 110 and the third glass substrate 130 and extend to cover the bending area BA in which the third glass substrate 130 is disposed. Therefore, the etch stop layer 610 may be formed to extend further to cover a portion of the rear flat area RFA where the glass substrate 100 is separated into the second glass substrate 120 and the third glass substrate 130.

The etch stop layer 610 may be formed of multiple layers. The etch stop layer 610 may include, for example, a first planarization layer 611, a second planarization layer 612 disposed on the first planarization layer 611, and a bank layer (not illustrated) disposed on the second planarization layer 612. For example, the etch stop layer 610 may be formed using various organic/inorganic films used in the pixel array layer 210 when forming the planarization layer and the bank layer. Additionally, the etch stop layer 610 may be formed using a metal layer used to form a layer in the pixel array layer 210.

A signal line(s) S/L disposed at the pixel array layer 210 may extend to the bending area BA and may be electrically connected to a plurality of data pad electrodes disposed on the display pad portion 220. The etch stop layer 610 may be disposed on the substrate in the bending area BA. The signal line(s) S/L disposed and bent in the bending area BA may be defined as bending line(s) 614.

The bending line(s) 614 may be formed inside the etch stop layer 610. The bending line(s) 614 may be additionally formed with a pattern PTN to reduce a tensile force during bending, and a buffer layer formed with the pattern PTN may be additionally disposed below the bending line(s) 614.

The first micro coating layer 621 may be disposed on the etch stop layer 610 and the bending line(s) 614. Cracks may occur in the bending line(s) 614 due to the tensile force applied during bending. Therefore, the first micro coating layer 621 may be formed to a small thickness at a position where a resin is bent and may serve to protect the bending line(s) 614 (or signal line(s) S/L). The first micro coating layer 621 may be made of an acrylic material, such as an acrylate polymer, but is not necessarily limited thereto. One or more of various resins may be applied without limitation.

The first micro coating layer 621 may control a neutral surface NS of the bending area BA. The neutral surface NS may be a virtual surface where a structure does not receive stress because the compressive force and tensile force applied to the structure cancel each other when the structure is bent. Where two or more structures are stacked, a virtual neutral surface NS may be formed between the structures.

When an entire structure is bent in one direction, structures disposed in a bending direction based on the neutral surface NS may be compressed by bending and thus receive a compressive force. Conversely, structures disposed in a direction opposite to the bending direction based on the neutral surface NS may be stretched by bending and thus receive a tensile force. In addition, structures are more vulnerable when subjected to a tensile force than to a compressive force having the same strength. Accordingly, there is a higher probability of cracks occurring when subjected to the tensile force.

Based on the neutral surface NS, the glass substrate 100 disposed below may be compressed and thus receive a compressive force, and the etch stop layer 610 disposed above may receive a tensile force. Accordingly, cracks may occur due to this tensile force. Therefore, to minimize or reduce the tensile force received by the bending lines 614, the first micro coating layer 621 may be disposed on the etch stop layer 610 in the bending area BA.

By arranging the first micro coating layer 621 in the bending area BA, the neutral surface NS may be raised upward. The neutral surface NS may be configured to be at the same vertical position as the bending lines 614 or be at a higher vertical position than the bending lines 614. Thus, the bending lines 614 may be less susceptible to stress by being subjected to a compressive force instead of a tensile force during bending, thereby suppressing the occurrence of cracks in the bending lines 614.

The etch stop layer 610 may be disposed between the display pad portion 220 and the pixel array layer 210.

The etch stop layer 610 may include, for example, a plurality of data pad electrodes disposed in the display pad portion 220, a plurality of data link lines connected to signal lines disposed in the pixel array layer 210, a plurality of gate pad electrodes disposed on the display pad portion 220, and a plurality of gate link lines connected to the driving circuit. The bending lines 614 may include one or more of the data link lines and gate link lines. Alternatively, the bending lines 614 may be extensions of the signal lines in the pixel array layer 210.

As shown in FIG. 5B, a process of etching the glass substrate 100 may be performed using a mask (MASK). The mask may include at least two holes H1 and H2 to separate the glass substrate 100 into the first glass substrate 110, the second glass substrate 120, and the third glass substrate 130. The mask may additionally include one or more micro-pattern holes mPTN to form the pattern(s) PTN of the third glass substrate 130 disposed in the bending area BA. In this case, laser cutting or wheel cutting processes may be used to pattern the mask.

Next, the glass substrate 100 may be etched using the disposed mask as shown in FIGS. 5B and 5C and may be separated into the first glass substrate 110, the second glass substrate 120, and the third glass substrate 130 disposed to overlap the bending area BA of the display device. Here, a glass etching process may be performed as a wet etching process rather than a dry etching process. In the process of etching the glass substrate 100, the etched surfaces of the first glass substrate 110 or the second glass substrate 120 may be configured in a tapered shape. In the third glass substrate 130, a pattern PTN may be formed by a mask micro-pattern hole mPTN.

The etching process may be performed simultaneously with a glass substrate thinning process. After performing the thinning process, the thickness of the glass substrate 100 may range from 0.05 to 0.2 mm. However, the thickness of the glass substrate is not limited to this range, and any thickness of the glass substrate 100 applied to a display device in the art may be used without limitation.

As shown in FIGS. 5D and 5E, the third glass substrate 130 may be further etched to reduce stress during bending of the third glass substrate 130. Finally, a thickness T2 of the third glass substrate may be smaller than a thickness T1 of each of the first glass substrate 110 and the second glass substrate 120.

The second micro coating layer 622 may be additionally applied to an etched empty space between the first glass substrate 110 and the third glass substrate 130 and between the second glass substrate 120 and the third glass substrate 130. By applying the second micro coating layer 622, the stress applied to the third glass substrate 130 and the etch stop layer 610 in the bending area BA during bending can be reduced. The second micro coating layer 622 may be made of the same or similar material(s) as the first micro coating layer 621.

As illustrated in FIG. 5F, a second adhesive layer 101 may be disposed below one or both of the first glass substrate 110 and the second glass substrate 120 so that the second glass substrate 120 may be adhered to the rear surface of the first glass substrate 110 when bent or folded. As the second glass substrate 120 is adhered and disposed on the rear surface of the first glass substrate 110, an area (e.g., a lateral area) of the non-display area NDA may be reduced to implement a narrow bezel, thereby reducing the unnecessary space of the display device 1000.

A flexible circuit film 710 may be disposed on the display pad portion 220. A display driver 700 may be mounted on the flexible circuit film 710 by a chip bonding process or a surface mounting process. The display driver 700 may generate a data signal and a gate control signal based on image data and timing synchronization signals supplied from an external display driving system and may supply the data signal to the data line of each pixel supply and the gate control signal to the driving circuit.

Alternatively, instead of being mounted on the flexible circuit film 710, the display driver 700 may be directly mounted on and electrically connected to the display pad portion 220 disposed on the second glass substrate 120 and may be electrically connected to each of a pixel driving signal line and a gate driving circuit provided in the pixel array layer 210. In this case, the flexible circuit film 710 may serve to relay signal transmission between the pad portion and the external display driving system.

A source printed circuit board (S-PCB) 900 may be disposed on one side of the flexible circuit film 710.

A data driver configured to drive the display device 1000 may be mounted on the S-PCB 900.

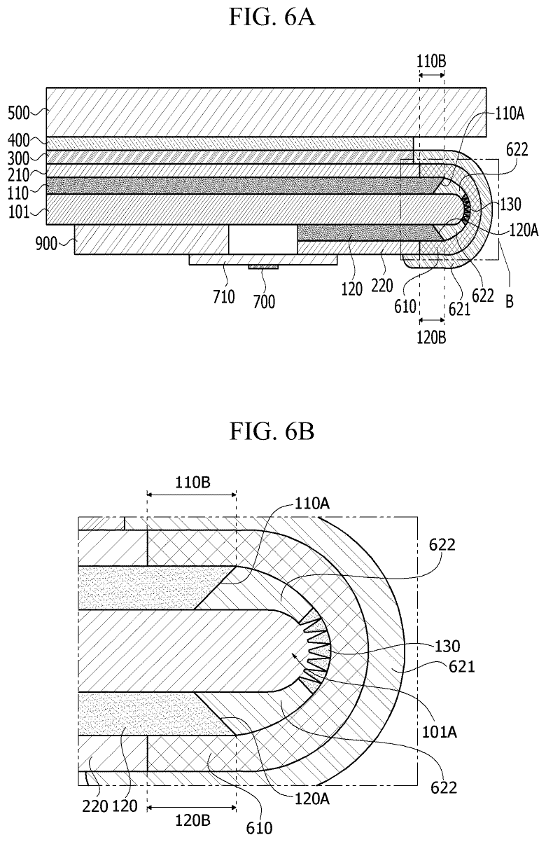

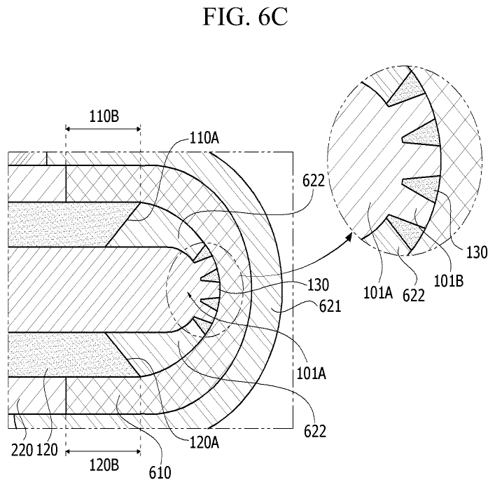

FIG. 6A is a cross-sectional view of a display device according to an example embodiment of the present disclosure.

Since the display device shown in FIG. 6A is the same as or similar to the display device shown in FIG. 5F except for the structure or configuration of the bending area BA, redundant descriptions are omitted.

As shown in FIG. 6A, the third glass substrate 130 and the etch stop layer 610 disposed in the bending area BA may be bent.

The etch stop layer 610 may cover each of (1) an upper portion of one side 110B of the first glass substrate 110 where the etched surface 110A of the first glass substrate 110 is disposed, (2) the third glass substrate 130 in the bending area BA, and (3) an upper portion (or a lower portion in the bent or folded state) of one side 120B of the second glass substrate 120 where the etched surface 120A of the second glass substrate 120 is disposed.

To distribute stress during bending of the third glass substrate 130 and the etch stop layer 610, first and second micro coating layers 621 and 622 may be disposed on an upper portion of the etch stop layer 610 and at the left and right sides (or at both ends) of the third glass substrate 130, respectively. The first micro coating layer 621 covering the etch stop layer 610 may be disposed in the bending area BA from the upper portion of one side 110B of the first glass substrate 110 where the etched surface 110A of the first glass substrate 110 is disposed to the upper portion (or a lower portion in the bent or folded state) of one side 120B of the second glass substrate 120 where the etched surface 120A of the second glass substrate 120 is disposed. The second micro coating layer 622 may be applied to fill areas below the etch stop layer 610 between a tapered etched surface 110A of the first glass substrate 110 and one side of the third glass substrate 130 and between the other side of the third glass substrate 130 and a tapered etched surface 120A of the second glass substrate 120.

After being bent or folded, the second glass substrate 120 with the display pad portion 220 disposed thereon may be adhered to the rear surface of the first glass substrate 110 by the second adhesive layer 101 on a rear surface of the first glass substrate 110 to form the rear flat area RFA.

As the second glass substrate 120 is adhered and disposed on the rear surface of the first glass substrate 110, an area (e.g., a lateral area) of the non-display area NDA may be reduced to implement a narrow bezel, thereby reducing the front surface of the display device 1000 not used for displaying an image.

FIG. 6B is an enlarged cross-sectional view of a portion of the bending area, which is area B in FIG. 6A. FIG. 6C is an enlarged view of a portion of the bending area according to another embodiment of the present disclosure.

As illustrated in FIGS. 6B and 6C, an etched surface 110A of the first glass substrate 110 and an etched surface 120A of the second glass substrate 120 are each configured in a tapered shape. By bending the third glass substrate 130 disposed in the bending area BA, the second glass substrate 120 may be disposed in the rear flat area RFA, and the etched surface 110A of the first glass substrate 110 and the etched surface 120A of the second glass substrate 120 may be disposed at opposing angles or diverging angles.

The second adhesive layer 101 may protrude or extend to the bending area due to pressure during bending, thereby forming a protruding portion 101A. An outermost side 101B of the protruding portion 101A may be in contact with the bent third glass substrate 130.

Additionally, as shown in FIG. 6C, the outermost side 101B of the protruding portion 101A of the second adhesive layer 101 may be filled between the pattern(s) PTN or fill a space in the pattern(s) PTN of the third glass substrate and may be in contact with a lower surface of the etch stop layer 610.

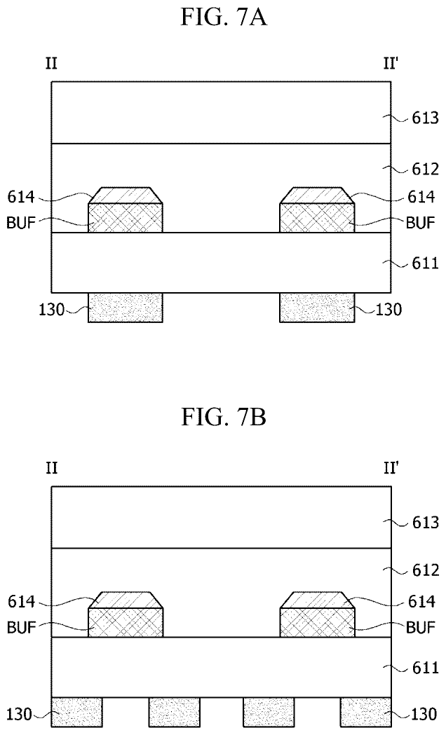

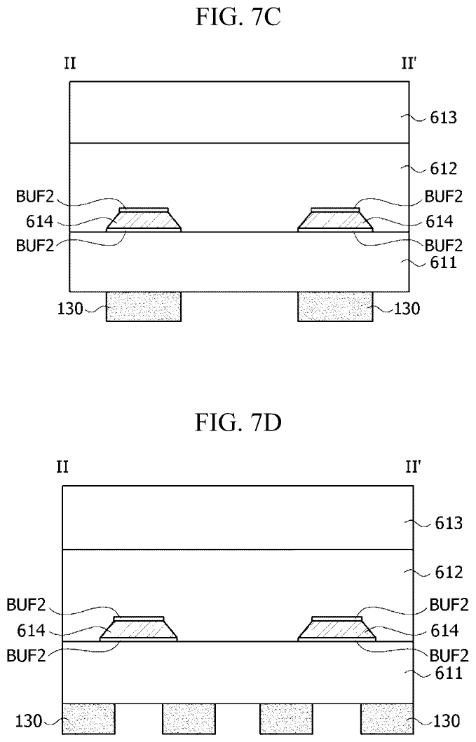

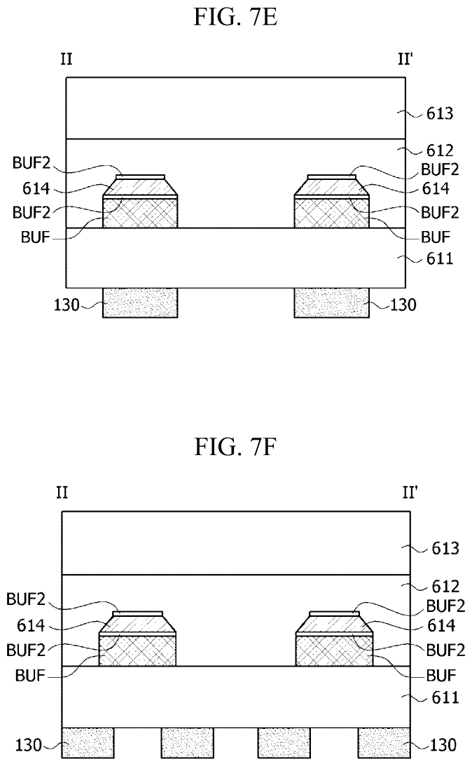

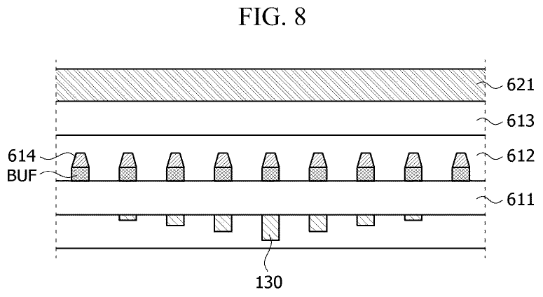

FIGS. 7A to 7F are cross-sectional views illustrating various examples of one or more bending lines 614 of a link line part and a third glass substrate 130 disposed in a bending area of a display device according to example embodiments of the present disclosure. FIG. 8 is an enlarged view of a bending area according to still another embodiment of the present disclosure.

FIG. 7A is a cross-sectional schematic diagram showing the etch stop layer 610 disposed in the bending area BA, and the first and second micro coating layers 621 and 622 are omitted for convenience of description. The etch stop layer 610 may include the first planarization layer 611, the second planarization layer 612 disposed on the first planarization layer 611, and the bank layer 613 disposed on the second planarization layer 612. In another example, the bank layer may be disposed on the etch stop layer and a coating layer may be disposed on the bank layer. The third glass substrate 130 with a pattern PTN may be disposed below the first planarization layer 611. At least one of the first planarization layer 611 and the second planarization layer 612 may cover a portion of the first glass substrate 110 and the second glass substrate 120.

The second planarization layer 612 of the etch stop layer 610 may include the bending line(s) 614 connected to a driving circuit or a gate or a data line of a pixel. The bending line(s) 614 may include multiple conductive metal layers. The bending line (or conductive line) 614 may be disposed between the first planarization layer 611 and the second planarization layer 612, and may be electrically connected to at least one of the plurality of pixels and the display driver or display pad. The bending line (or conductive line) 614 may be bent along with the third glass substrate 130. The bending line(s) 614 may include multiple metal layers such as Ti/Al/Ti. The bending line(s) 614 may be formed in an area corresponding to the bending area BA, and the pattern PTN may be disposed to distribute the stress that may occur during bending or folding of the bending area BA. The bending line(s) 614 may be formed to have a pattern that is the same as, or matches or corresponds to, the pattern PTN of the third glass substrate 130.

Here, the same (or matching or corresponding) pattern means that, if the pattern PTN of the third glass substrate 130 and the pattern of the bending line(s) 614 are folded along an imaginary line between them, the patterns would entirely or substantially overlap. This is shown for example in FIGS. 7A, 7C, and 7E.

The buffer layer BUF may be disposed below the patterned bending lines 614 to distribute the stress generated during bending. The buffer layer BUF may be formed of one or more layers of an SiNₓ layer and an SiO₂ layer. In one example configuration, the buffer layer BUF may be formed of alternating stacks of SiNₓ layers and SiO₂ layers.

It may be preferable in some applications to match the patterning of the bending line(s) 614 with the pattern of the third glass substrate 130 as shown, for example, in FIGS. 7A, 7C, and 7E. However, as shown in FIGS. 7B, 7D, and 7F, the patterning of the bending lines 614 and the patterning of the third glass substrate 130 may be different or not match.

As shown in FIGS. 7C and 7D, the bending line(s) 614 of the etch stop layer 610 may include a MoTi/Al/MoTi bending line by additionally stacking metals as second buffer layers BUF2 on upper and lower portions of the bending lines 614 to reduce stress during bending.

As shown in FIGS. 7E and 7F, the bending line(s) 614 in the etch stop layer 610 may include a first buffer layer BUF on a lower portion of the Mo/Ti/Al/Mo/Ti bending line(s) 614 in which metals such as Mo are additionally stacked on the upper and lower portions of the bending line(s) 614 to reduce stress during bending. The constituent layers and constituent materials of the bending line(s) are not limited thereto, and a single layer such as Al, Cu, etc., multi-layer lines such as MoTi/Al/MoTi, Cu, Ti/Cu/Ti, etc., or single or multiple metal layers having sufficient elongation and resistivity for use in signal lines for display devices, e.g., OLED displays, may be used.

Since the etch stop layer 610 (including, for example, a first planarization layer 611 and a second planarization layer 612) shown in FIG. 8 is the same as or similar to the etch stop layer 610 shown in FIGS. 6A to 6C (or in FIGS. 5A to 5F or FIGS. 7A to 7F) except for the structure of the bending area BA, redundant descriptions are omitted.

As shown in FIG. 8, the thickness of the third glass substrate 130 disposed in the bending area BA may be the largest at the center of the bending area BA, which would be located on an outermost side after bending. The third glass substrate 130 may have a greater thickness at a central portion than at a periphery portion. Portions of the third glass substrate 130 adjacent to the first glass substrate 110 and the second glass substrate 120 (or the inner portions of the third glass substrate 130 after bending) may be additionally etched to be thinner or completely removed. The second micro coating layer 622 may be applied to fill the space formed by etching the third glass substrate 130.

Various example embodiments of the present disclosure may be described as follows.

A display device according to one or more example embodiments may include: a substrate; a display area on the substrate, the display area including a plurality of pixels; a non-display area outside the display area on the substrate and including a display driver; and a bending area between the display area and the non-display area. The substrate may include a first glass substrate in the display area, a second glass substrate in the non-display area, and a third glass substrate in the bending area and having a pattern.

In some example embodiments, the pattern may include a mesh or zigzag shape.

In some example embodiments, the display device may further include an etch stop layer disposed on the first glass substrate, the second glass substrate, and the third glass substrate.

In some example embodiments, the etch stop layer may include a first planarization layer on the third glass substrate and a second planarization layer on the first planarization layer. The display device may further include a bending line disposed between the first planarization layer and the second planarization layer, the bending line being electrically connected to at least one of the plurality of pixels and the display driver.

In some example embodiments, the display device may further include a coating layer disposed between the third glass substrate and the first glass substrate and between the third glass substrate and the second glass substrate.

In some example embodiments, the display device may further include a bank layer on the etch stop layer and a coating layer on the bank layer.

In some example embodiments, the display device may further include at least one buffer layer disposed on or below the bending line.

In some example embodiments, the bending line may be formed in a pattern, and the pattern of the bending line may match the pattern of the third glass substrate.

In some example embodiments, a thickness of the third glass substrate may be smaller than a thickness of each of the first and the second glass substrates.

In some example embodiments, the third glass substrate may have a greater thickness at a central portion than at a periphery portion.

A display device according to one or more example embodiments may include: a first substrate including a plurality of pixels configured to display an image; a second substrate spaced apart from the first substrate and including a display pad electrically connected to at least one of the pixels; and a third substrate between the first substrate and the second substrate, the third substrate being formed in a pattern and being bent. The third substrate may have a smaller thickness than each of the first substrate and the second substrate.

In some example embodiments, the patten of the third substrate may have a mesh or zigzag shape extending in a direction diagonal to a bending direction of the third substrate.

In some example embodiments, the display device may further include a conductive line on the third substrate and electrically connected to the at least one of the pixels and the display pad, the conductive line being bent along with the third substrate.

In some example embodiments, the conductive line may be formed in a pattern, and the pattern of the conductive line may match the pattern of the third substrate.

In some example embodiments, the display device may further include a first planarization layer between the third substrate and the conductive line, a second planarization layer on the conductive line, and a coating layer on the second planarization layer.

In some example embodiments, at least one of the first planarization layer and the second planarization layer may cover a portion of the first substrate and the second substrate.

In some example embodiments, the display device may further include an adhesive layer on a rear surface of the first substrate. The second substrate may be attached to the rear surface of the first substrate via the adhesive layer.

In some example embodiments, the adhesive layer may contact the third substrate.

In some example embodiments, the display device may further include an etch stop layer on the third substrate. The adhesive layer may fill a space in the pattern of the third substrate and contacts the etch stop layer.

In some example embodiments, the display device may further include a coating layer in a space between the third substrate and the first substrate and in a space between the third substrate and the second substrate.

In some example embodiments, wherein the first, second, and third substrates may be glass substrates.

In some example embodiments, the third substrate may have a greater thickness at a central portion than at a periphery portion.

According to embodiments of the present disclosure, a display device can be provided with a display area substrate, a bending area substrate, and a non-display area substrate that may be formed through process optimization without performing any additional processing or with a reduced amount of additional processing. In addition, according to embodiments of the present disclosure, a display device with improved reliability of a bending area, a reduced size of the bending area, and thus a reduced width of a bezel area can be provided.

The advantages and effects according to the present disclosure are not limited to those described above, and additional advantages and effects are included in the present disclosure or may be understood by those skilled in the art from the present disclosure.

It will be apparent to those skilled in the art that the present disclosure is not limited by the above-described example embodiments and the accompanying drawings, and that various substitutions, modifications, and variations can be made in the present disclosure without departing from the spirit or scope of the disclosures. Therefore, the above example embodiments of the present disclosure are provided for illustrative purposes and are not intended to limit the scope or technical concept of the present disclosure. The protective scope of the present disclosure should be construed based on the following claims and their equivalents, and it is intended that the present disclosure cover all modifications and variations of this disclosure that come within the scope of the claims and their equivalents.

What is claimed is:

1. A display device, comprising:
a substrate;
a display area on the substrate, the display area including a plurality of pixels;
a non-display area outside the display area on the substrate and including a display driver; and
a bending area between the display area and the non-display area,
wherein the substrate includes:
a first glass substrate in the display area;
a second glass substrate in the non-display area; and
a third glass substrate in the bending area and having a pattern.

2. The display device of claim 1, wherein the pattern includes a mesh or zigzag shape.

3. The display device of claim 1, further comprising an etch stop layer disposed on the first glass substrate, the second glass substrate, and the third glass substrate.

4. The display device of claim 3, wherein:
the etch stop layer includes a first planarization layer on the third glass substrate and a second planarization layer on the first planarization layer; and
the display device further comprises a bending line disposed between the first planarization layer and the second planarization layer, the bending line being electrically connected to at least one of the plurality of pixels and the display driver.

5. The display device of claim 4, further comprising:
a coating layer disposed between the third glass substrate and the first glass substrate and between the third glass substrate and the second glass substrate.

6. The display device of claim 4, further comprising:
a bank layer on the etch stop layer; and
a coating layer on the bank layer.

7. The display device of claim 4, further comprising at least one buffer layer disposed on or below the bending line.

8. The display device of claim 4, wherein:
the bending line is formed in a pattern; and
the pattern of the bending line matches the pattern of the third glass substrate.

9. The display device of claim 1, wherein a thickness of the third glass substrate is smaller than a thickness of each of the first and the second glass substrates.

10. The display device of claim 1, wherein the third glass substrate has a greater thickness at a central portion than at a periphery portion.

11. A display device, comprising:
a first substrate including a plurality of pixels configured to display an image;
a second substrate spaced apart from the first substrate and including a display pad electrically connected to at least one of the pixels; and
a third substrate between the first substrate and the second substrate, the third substrate being formed in a pattern and being bent,
wherein the third substrate has a smaller thickness than each of the first substrate and the second substrate.

12. The display device of claim 11, wherein the patten of the third substrate has a mesh or zigzag shape extending in a direction diagonal to a bending direction of the third substrate.

13. The display device of claim 11, further comprising:
a conductive line on the third substrate and electrically connected to the at least one of the pixels and the display pad, the conductive line being bent along with the third substrate.

14. The display device of claim 13, wherein:
the conductive line is formed in a pattern; and
the pattern of the conductive line matches the pattern of the third substrate.

15. The display device of claim 13, further comprising:
a first planarization layer between the third substrate and the conductive line;
a second planarization layer on the conductive line; and
a coating layer on the second planarization layer,
wherein at least one of the first planarization layer and the second planarization layer covers a portion of the first substrate and the second substrate.

16. The display device of claim 11, further comprising:
an adhesive layer on a rear surface of the first substrate,
wherein the second substrate is attached to the rear surface of the first substrate via the adhesive layer.

17. The display device of claim 16, wherein the adhesive layer contacts the third substrate.

18. The display device of claim 17, further comprising:
an etch stop layer on the third substrate,
wherein the adhesive layer fills a space in the pattern of the third substrate and contacts the etch stop layer.

19. The display device of claim 11, further comprising:
a coating layer in a space between the third substrate and the first substrate and in a space between the third substrate and the second substrate.

20. The display device of claim 11, wherein the first, second, and third substrates are glass substrates.
